(19) United States
(12) Patent Application Publication
(10) Pub. No.: US 2005/0045485 A1
(43) Pub. Date: Mar. 3, 2005

(54) Method to improve copper electrochemical deposition

(75) Inventors: Chien-Hsueh Shih, Taipei (TW); Ting-Chu Ko, Taipei (TW); Minghsing Tsai, Taipei (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co. Ltd.

(21) Appl. No.: 10/654,523

(22) Filed: Sep. 3, 2003

(51) Int. Cl. C25D 5/02; H01L 21/445

(52) U.S. Cl. 205/123; 205/291

(57) ABSTRACT

A method for reducing or avoiding copper layer pitting in a copper electrochemical deposition process to improve deposition uniformity including providing a substrate for carrying out at least a first copper electroplating process; providing a copper electroplating solution including a deforming (antiforming) agent wherein the antiforming (deforming) agent includes at least one alkylene monomer; and, carrying out at least a first copper electroplating process to deposit at least a first copper layer.

### FIELD OF THE INVENTION

This invention generally relates to electrochemical deposition (ECD) methods and electrolyte solutions and more particularly to methods for improving a copper plating solution to reduce plating solution bubble formation and improve copper ECD in a micro-integrated circuit manufacturing process.

### BACKGROUND OF THE INVENTION

Sub-micron multi-level metallization is one of the key technologies for the next generation of ultra large scale integration (ULSI). The multilevel interconnects that lie at the heart of this technology require planarization of interconnect features formed in high aspect ratio apertures, including contacts, vias, metal interconnect lines and other features. Reliable formation of these interconnect features is very important to the success of ULSI and to the continued effort to increase circuit density and quality on individual substrates and die.

Copper and copper alloys have become the metal of choice for filling sub-micron, high aspect ratio interconnect features on semiconductor substrates. Copper and its alloys have lower resistivity and higher electromigration resistance compared to other metals such as, for example, aluminum. These characteristics are critical for achieving higher current densities increased device speed.

As circuit densities increase, the widths of vias, contacts, metal interconnect lines, and other features, decrease to sub-micron dimensions, whereas the thickness of the dielectric layers, through the use low-k (low dielectric constant) materials, has remained substantially constant. Consequently, the aspect ratios for the features, i.e., their height divided by width, has increased thereby creating additional challenges in adequately filling the sub-micron features with, for example, copper metal. Many traditional deposition processes such as chemical vapor deposition (CVD) have difficulty filling increasingly high aspect ratio features, for example, where the aspect ratio exceeds 2:1, and particularly where it exceeds 4:1.

As a result of these process limitations, electrochemical deposition (ECD), also referred to as electroplating or electrolytic deposition, is now a preferable method for filling copper interconnect structures such as via openings and trench line openings in multi-layer semiconductor devices. Typically, ECD uses an electrolyte including positively charged ions of deposition material, for example metal ions, in contact with a negatively charged substrate (cathode) having a source of electrons to deposit (plate out) the metal ions onto the charged substrate, for example, a semiconductor wafer. A thin metal layer (seed layer) is first deposited onto the semiconductor wafer to form a liner in high aspect ratio anisotropically etched features to provide a continuous electrical path across the plating surface. An electrical current is supplied to the seed layer whereby the semiconductor wafer surface including etched features are electroplated with copper to fill the features.

In filling via openings and trench line openings with copper, electroplating is a preferable method to achieve superior step coverage of sub-micron etched features. The method generally includes first depositing a barrier layer over the etched opening surfaces, such as via openings and trench line openings, depositing a copper seed layer over the barrier layer, and then electroplating copper over the seed layer to fill the etched features to form conductive vias and trench lines. The electrodeposited copper layer, the barrier layer, and the insulating layer are then planarized, for example, by chemical mechanical polishing (CMP), to define a copper interconnect feature within a layer of a multi-layer semiconductor device.

Metal electroplating (electrodeposition) in general is a well-known art and can be achieved by a variety of techniques. Common designs of cells for electroplating copper on semiconductor wafers involve positioning the plating surface of the semiconductor wafer within an electrolyte plating solution including an anode assembly with the electrolyte impinging perpendicularly on the plating (cathode) surface. The electrodeposition (plating) surface, such as a copper seed layer is contacted with an electrical power source to form the cathode of the plating system such that copper ions in the plating solution deposit on the electrodeposition surface, for example a semiconductor wafer surface, where they are reduced to copper metal. A common electrolyte plating solution includes a dissolved copper salt such as copper sulfate, an acid such as sulfuric acid, and additives such as surfactants, brighteners, levelers and suppressors, to improve the quality of the electroplating process.

Methods of the prior art have addressed several problems peculiar to copper ECD in filling high aspect ratio features in semiconductor integrated circuit manufacture. Some problems that manifest themselves include the conformal nature of the copper deposition and the formation of keyholes and voids that occur when the top of the opening prematurely closes in the plating process. Other problems have been associated with defects that occur at the end of the plating process where copper dendrites or protrusions may form on the copper surface from the electrolyte plating solution. Various approaches including varying the magnitude, timing, and polarity of the current density during the deposition process have been proposed for overcoming some of the problems peculiar to copper plating of high aspect ratio openings.

Despite various approaches proposed, nonuniformities in a copper plating process continue to manifest themselves, such as the formation of pits within the electroplated copper layer.

These and other shortcomings demonstrate a need in the semiconductor processing art to develop an improved method for copper electrochemical deposition (ECD) such that copper electrodeposition uniformity is improved including preventing the formation of pitting defects within the deposited copper layer.

It is therefore an object of the invention to provide an improved method for copper electrochemical deposition (ECD) such that copper electrodeposition uniformity is improved including preventing the formation of pitting defects within the deposited copper layer while overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for reducing or avoiding copper layer pitting in a copper electrochemical deposition process to improve deposition uniformity.

In a first embodiment, the method includes providing a substrate for carrying out at least a first copper electroplating process; providing a copper electroplating solution including a deforming (antiforming) agent wherein the antiforming (deforming) agent includes at least one alkylene monomer; and, carrying out at least a first copper electroplating process to deposit at least a first copper layer.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1E are cross sectional representations of a portion of a multi-layer semiconductor device showing a stage in a dual damascene manufacturing process according to an embodiment of the present invention.

FIG. 2 is a process flow diagram including several embodiments of the present invention.

### DETAILED DESCRIPTION OF THE PREFERRED EMBODIMENTS

In the method and copper plating solution according to the present invention, the invention is explained by reference to electroplating of copper to fill a high aspect ratio opening, for example, a dual damascene structure. It will be appreciated, however, that the method of the present invention may be advantageously applied to the electroplating of single damascene structures as well as wide area trenches and bonding pads. It will be appreciated that the term copper as used herein refers to copper and alloys thereof.

In one embodiment of the invention, a copper plating solution is provided for carrying an electrochemical deposition (ECD) process on a substrate. The copper plating solution includes at least one soluble copper salt, an electrolyte, and a deforming (anti-forming) agent. The anti-forming agent is added at least prior to beginning the electroplating process to improve wetting of a copper seed layer to reduce generation of gaseous bubbles forming on the copper seed layer and improve copper layer deposition uniformity and integrity to avoid copper layer pitting. The copper ECD (electroplating) process is then carried out according to preferred embodiments.

It has been found that the generation of gaseous bubbles at the surface of the copper seed layer, for example bubbles generated by liquid surface fluctuations during substrate loading or hydrogen generated by chemical reactions associated with the reduction of copper from the plating solution onto the copper seed layer, interferes with wetting of the copper seed layer by the copper plating solution which inhibits uniform deposition of copper onto the plating surface. The formation of gaseous bubbles is particularly a problem at the beginning of the copper plating process but may continue and interfere with copper deposition throughout the copper plating process. As a result, pitting has been found to occur at the surface of the deposited copper layer both following the ECD process or following a CMP process to remove excess overlying copper and define copper metal interconnects, for example damascene or dual damascene structures.

It has been found that the generation of gaseous bubbles at the plating surface during the ECD process is particularly enhanced when filling high aspect ration features, for example having a depth to width dimension of greater than about 4 and for sub quarter micron diameter features, for example vias having a diameter less than about 0.25 microns, more preferably less that about 0.15 microns, for example about 0.1 micron. The presence of the gas bubbles at the surface is believed to be enhanced by the low interfacial energy of the plating surface. Hence, the increased propensity for gaseous bubbles to form during the electroplating process and adhere to the plating surface, particularly the copper seed layer.

It has been found that by adding an appropriate concentration of one or more deforming (anti-forming) agents to form a high surface tension plating surface, for example greater than about 50 dynes/cm, that the formation of gaseous bubbles in the plating solution and on the copper seed layer is significantly reduced and the consequent appearance of pitting in the copper layer is substantially reduced.

In a preferred embodiment, the anti-forming (deforming) agent preferably includes at least one of an alkylated glycol such as polyalkylene glycols or polyalkylene glycol ethers. In another embodiment, the anti-forming agent includes a polyalkylene oxide copolymer including an alkylene such as ethylene, propylene, or butylenes, more preferably including at least one of an ethylene oxide copolymer and propylene oxide copolymer. In another embodiment, the anti-forming agent includes amine based polyalkylene oxide copolymers, including amine substituents such as diamines or tri-amines where the alkylene is ethylene, propylene, or butylene. For example, the anti-forming agent preferably includes an amine based polyalkylene oxide where the alkylene is ethylene, propylene, or butylene. For example, preferably, the anti-forming agent is added to the copper plating solution at a concentration of about 5 to about 1000 ppm, more preferably between about 50 and about 500 ppm with respect to the copper plating solution.

Preferably, the copper plating solution additionally includes one or more suppressor agents. There are many types of suitable suppressor agents including high molecular weight polyethers, for example having a molecular weight greater than about 800. Other types of suppressor agents useful in the present invention include ethoxylated amines, alkylpolyether sulfonates, and alkoxylated diamines. For example, in a preferred embodiment, the suppressor agent concentration together with the one or more anti-forming agents is added at a concentration of about 10 ppm to about 1000 ppm with respect to the copper plating solution.

In another embodiment, the one or more suppressor agents are added to the copper plating solution after the beginning of the plating process, preferably after the copper seed layer is covered by plated copper, to enhance the effect of the anti-forming agent and allow copper plating to occur more uniformly at the beginning of the copper plating process.

The copper electroplating solution preferably additionally includes at least one soluble copper salt, an electrolyte and one or more anti-forming agents according to preferred embodiments. The electrolyte is preferably an acidic aqueous medium including, for example, a sulfuric acid solution with a chloride or other halide ion source; and one or more brightener agents. It will be appreciated however, that neutral or mildly basic electrolytes, for example having a pH less than about 9.0 may be used as well. The copper plating solution may optionally include leveler agents and brighteners. The brightener may be optionally present in the copper plating solution at the beginning of the plating process, including a reduced concentration and may be added throughout the plating process. In one embodiment it is desirable to delay adding the brightener until after an initial layer of copper has been deposited to at least cover the copper seed layer to increase the effectiveness of the anti-forming agents. The leveler, may be added prior to or during the copper plating process, but is preferably added following initial deposition of copper for the same reasons. For example, leveler, brightener, and suppressor may be advantageously added after filling about 25 percent to about 75 percent of a deposition opening volume.

Several copper salts are suitable for use with the present invention, including for example, copper sulfates, copper acetates, and cupric nitrates. For example, the copper salt is typically added at a concentration of from about 5 to about 500 grams per liter of plating solution, more preferably at a concentration of from about 50 to about 150 grams per liter of plating solution. A brightener agent is preferably added at a concentration of about 1 ppm to about 50 ppm of plating solution. Suitable brighteners may include, for example, compounds that have sulfide and/or sulfonic acid groups such as mercapto-alkylsulfonic acids, mercapto-alkyl sulfonates, as well as alkyl-dithiocarbamic acids.

For example, brightener agent is advantageously added following the beginning of the copper plating process, for example, following at least covering of the copper seed layer by plated copper. Preferably, brightener agent is added after filling about 25 to about 75 percent of the smallest critical dimension of the opening (i.e., conformal deposition process), or alternatively, about 25 percent to about 75 percent of the volume of the smallest portion of the opening, for example a via portion of a dual damascene structure. A smaller portion of the brightener agent may also be present at the beginning of the electroplating process, for example less than about 1 ppm, and subsequently added throughout the plating process at a higher concentration, for example about 50 ppm. It is believed that a lower level of copper plating solution additives at the beginning of the plating process aid the action of the anti-forming agent in producing a more uniform initial coating of copper and suppressing the formation of gaseous bubbles at the plating surface, particularly the copper seed layer.

In another embodiment, a portion of the anti-forming (deforming) agent is added before the beginning of a first electroplating process and again during the electroplating process to stay within preferred concentration ranges, for example at about the same time as the addition of suppressor agents, brightener agents, and leveling agents in a second electroplating process.

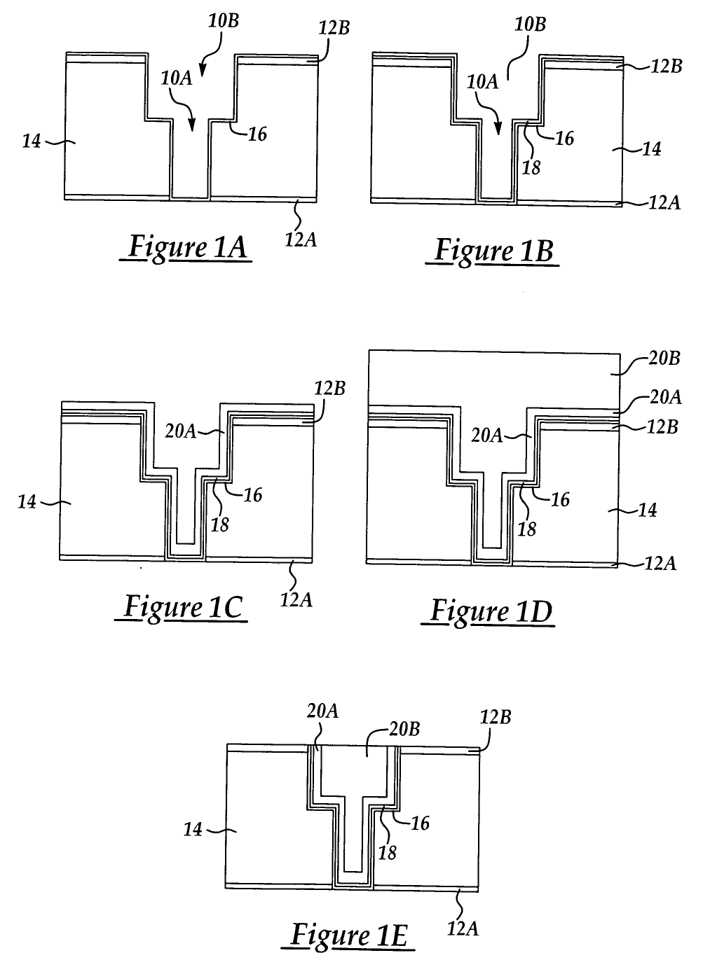

In an exemplary process, for example, referring to FIG. 1A, is shown a portion of a semiconductor wafer including an anisotropically etched dual damascene structure having a via opening portion 10A and an overlying trench line opening portion 10B. While there are several ways to form a dual damascene structure, one approach involves at least two photolithographic patterning and anisotropic etching steps to first form a via opening e.g., 10A, followed by a similar process to form an overlying trench line opening 10B. The dual damascene structure is formed in one or more dielectric insulating layers e.g., 14, for example a low dielectric constant material such as carbon doped oxide or organo-silicate glass (OSG), formed by plasma enhanced CVD (PECVD). The dielectric insulating layer is typically formed over an etch stop layer 12A, such as silicon nitride or silicon carbide and is capped by an anti-reflective coating (ARC) 12B, for example silicon nitride. The dielectric insulating layer may additionally include two separate dielectric insulating layers separated by a second etch stop layer (not shown).

Still referring to FIG. 1A, a barrier/adhesion layer 16, formed of at least one of a refractory metal or refractory metal nitride, for example, TaN, is blanket deposited to include covering the sidewalls and bottom portion of the via opening 10A and sidewalls of the trench opening 10B at a thickness of from about 25 Angstroms to about 100 Angstroms. The barrier/adhesion layer 16 serves the purpose of preventing copper diffusion into the surrounding dielectric insulating layer 14. Following barrier/adhesion layer deposition, a copper seed layer 18A is blanket deposited over the barrier layer 16 by for example, physical vapor deposition (PVD) at a thickness of from about 25 Angstroms to about 150 Angstroms. The copper seed layer 18 is preferably deposited to form a continuous layer to form a conductive surface for a subsequent electrodeposition process whereby an electrical potential is applied to the seed layer by cathode contacts contacting, for example, the outer peripheral edges of the semiconductor wafer.

Referring to FIG. 1C, according to a first step of an embodiment of the present invention, a first electroplating process is performed to electroplate a first copper layer portion to at least cover the copper seed layer with copper layer portion 20A. During the first electroplating process, the copper plating solution includes at least a copper salt, an electrolyte, and one or more anti-forming agents according to preferred embodiments. The first electroplating process is preferably carried out at a temperature range of about 0° C. to about 50° C., more preferably from about 10° C. to about 30° C. The first electroplating process is preferably carried to form a deposited layer extending across less than about 75 percent, more preferably equal to or less than about 50 percent of the critical dimension of the via portion of the dual damascene opening, e.g., 10A, for example having a critical dimension of less than about 0.2 microns, more preferably less than about 0.15 microns, for example 0.1 micron.

Referring to FIG. 1D, following the first electroplating process, a second electroplating process is carried out to complete the filling of the dual damascene opening with copper layer 20B where additional additives are added to the copper electroplating solution during the second electroplating process including at least one of brighteners, a suppressors, leveling agents, and additional antiforming (deforming) agents according to preferred embodiments. The second electroplating process may be carried out in the same electrochemical plating solution or may be carried out in a different plating solution. In the second electroplating process, the copper plating deposition is preferably deposited within the same temperature range as the first electroplating process and may optionally include deposition at a slightly lower temperature compared to the first electroplating process, for example from about 5° C. to about 10° C. lower, and may optionally include one or more interspersed electropolishing periods, for example, where the cathode and anode polarity are reversed for predetermined time periods between electrodeposition periods.

Referring to FIG. 1E, following the copper electroplating process, a conventional copper CMP process is carried out to remove the excess copper in layers 20A and 20B above the ARC layer level including removing the copper seed layer, barrier/adhesion layer, and at least a portion of the ARC layer 12B.

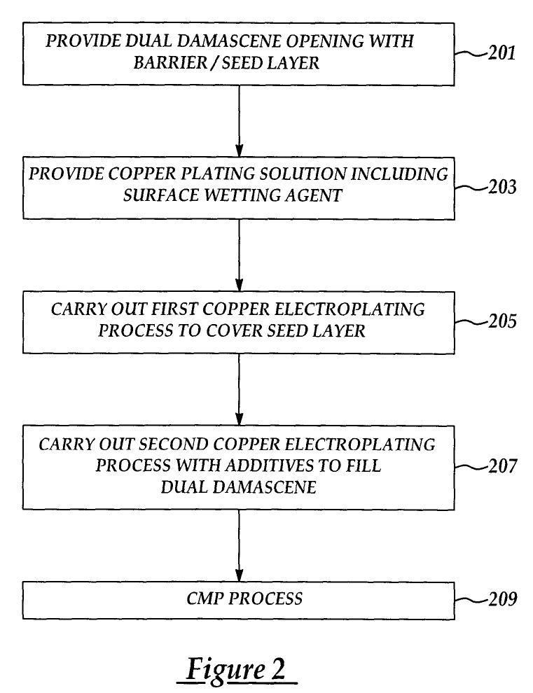

Referring to FIG. 2 is shown a process flow diagram including several embodiments of the present invention. In process 201, a dual damascene opening with a sub-quarter micron via is provided including a barrier layer and an overlying copper seed layer lining the opening. In process 203 a copper plating solution including one or more anti-forming (deforming) agents according to preferred embodiments is provided to increase a plating solution surface tension. In process 205, a first copper electroplating process is carried out for filling a portion of the opening to at least cover the copper seed layer e.g., deposit a copper layer filling from about 25 percent to about 75 percent of the via opening volume portion. In process 207, a second electroplating process is carried out to complete copper filling of the dual damascene opening including adding at least one of a suppressor, a brightener, a leveler, and additional deforming (antiforming) agent. At least one electropolishing period is optionally carried out during the second electroplating process. In process 209, a CMP process is carried out to remove excess copper and the barrier/adhesion layer above the trench level of the dual damascene structure.

The preferred embodiments, aspects, and features of the invention having been described, it will be apparent to those skilled in the art that numerous variations, modifications, and substitutions may be made without departing from the spirit of the invention as disclosed and further claimed below.

1. A method for reducing or avoiding copper layer pitting in a copper electrochemical deposition process to improve deposition uniformity comprising the steps of:
providing a substrate for carrying out at least a first copper electroplating process;
providing a copper plating solution comprising a deforming (antiforming) agent wherein the deforming agent comprises at least one alkylene monomer; and,
carrying out at least a first copper electroplating process to deposit at least a first copper layer.

2. The method of claim 1, wherein the antiforming (deforming) agent is selected from the group consisting of polyalkylene glycols, polyalkylene glycol ethers, polyalkylene oxide copolymers, and amine based polyalkylene oxide copolymers.

3. The method of claim 2, wherein the antiforming (deforming) agent comprises an alkylene monomer selected from the group consisting of ethylene, propylene and butylene.

4. The method of claim 2, wherein the polyalkylene oxide copolymers and amine based polyalkylene oxide copolymers comprise oxide groups selected from the group consisting of ethylene oxide, propylene oxide, and butylene oxide.

5. The method of claim 1, wherein the concentration of the antiforming (deforming) agent is between about 5 ppm and about 1000 ppm of copper plating solution.

6. The method of claim 1, wherein the concentration of the antiforming (deforming) agent is between about 50 ppm and about 500 ppm of copper plating solution.

7. The method of claim 1, wherein the at least a first copper electroplating process is carried out at a temperature from about 0° C. to about 50° C.

8. The method of claim 1, wherein the copper plating solution further comprises a copper salt.

9. The method of claim 8, the copper salt is selected from the group consisting of copper sulfates, copper acetates, and cupric nitrates.

10. The method of claim 1, wherein the substrate comprises a semiconductor process wafer comprising an opening extending through at least one dielectric insulator and a copper seed layer lining the opening the opening.

11. The method of claim 10, wherein the at least a first copper electroplating process is carried out to fill a portion of the opening to line less than about 75 percent of the smallest critical dimension.

12. The method of claim 11, wherein the opening is one of a damascene and dual damascene opening.

13. The method of claim 11, wherein the smallest critical dimension comprises a via opening diameter.

14. The method of claim 12, wherein a via opening portion comprises an aspect ratio of greater than about 4 to 1 and a diameter of less than about 0.15 microns.

15. The method of claim 11, further comprising a second copper electroplating process to deposit a second copper layer to fill the opening.

16. The method of claim 15 wherein the second copper electroplating process comprises the addition of at least one additive to the copper plating solution selected from the group comprising suppressors, brighteners, levelers, and the antiforming (deforming) agent.

17. The method of claim 16, wherein the second copper electroplating process is carried out at a temperature from about 5° C. to about 10° C. lower than the first copper electroplating process.

18. The method of claim 15, wherein the second copper electroplating process comprises at least one period of electropolishing a portion of the second copper layer.

19. A method for improving a copper electroplating process for filling high aspect ratio openings to reduce or avoid pitting defects comprising the steps of:
providing a semiconductor process wafer comprising a via opening extending through a thickness of at least one dielectric insulating layer including an uppermost copper seed layer lining the via opening;
providing a copper plating solution for carrying out at least a first copper electroplating process over the copper seed layer wherein the copper plating solution includes at least one copper salt, an electrolyte, and at least one deforming (antiforming) agent selected from the group consisting of polyalkylene glycols, polyalkylene glycol ethers, polyalkylene oxide copolymers, and amine base polyalkylene oxide copolymers;
carrying out the at least a first copper electroplating process to blanket deposit a first copper layer to cover the copper seed layer; and,
carrying out at least a second copper electroplating process to blanket deposit at least a second copper layer comprising the addition of additives to the copper plating solution selected from the group consisting of suppressors, brighteners, levelers, and the at least one deforming (antiforming) agent.

20. The method of claim 19, wherein the at least one deforming (antiforming) agent comprises at least one alkylene monomer selected from the group consisting of ethylene, propylene, and butylene.

21. The method of claim 19, wherein the at least one deforming (antiforming) agent is between about 50 ppm and about 500 ppm of copper plating solution.

22. The method of claim 19, wherein the first copper electroplating process is carried out at a temperature from about 0° C. to about 50° C.

23. The method of claim 19, wherein the at least a first copper electroplating process is carried out at a temperature from about 10° C. to about 30° C.

24. The method of claim 19, wherein the at least a second copper electroplating process is carried out at a temperature about 5° C. to about 10° C. lower than the first copper electroplating process.

25. The method of claim 19, wherein the at least a first copper electroplating process is carried out to substantially conformally fill from about 25 to about 75 percent of the via opening volume.

26. The method of claim 19, wherein the via opening diameter is less than about 0.25 microns.

27. The method of claim 19, wherein the second copper electroplating process comprises at least one period of electropolishing a portion of the second copper layer.

28. A copper electroplating solution for carrying out an electroplating process comprising:
an antiforming (deforming) agent comprising an alkylene containing monomer.

29. The copper electroplating solution of claim 28, further comprising an electrolyte and at least one copper salt.

30. The copper electroplating solution of claim 28, wherein the alkylene monomer is selected from the group consisting of ethylene, propylene, and butylene.

31. The copper electroplating solution of claim 28, wherein the antiforming (deforming) agent comprises a constituent selected from the group consisting of is selected from the group consisting of polyalkylene glycols, polyalkylene glycol ethers, polyalkylene oxide copolymers, and amine based polyalkylene oxide copolymers.

32. The copper electroplating solution of claim 31, wherein the polyalkylene oxide copolymers and amine based polyalkylene oxide copolymers comprise oxide groups selected from the group consisting of ethylene oxide, propylene oxide, and butylene oxide.

33. The copper electroplating solution of claim 28, further comprising additives selected from the group consisting of suppressors, brighteners, and levelers.

34. The copper electroplating solution of claim 28, wherein the antiforming (deforming) agent is provided at a concentration of from about 5 ppm to about 1000 ppm.

35. The copper electroplating solution of claim 28, wherein the antiforming (deforming) agent is provided at a concentration of from about 50 ppm to about 500 ppm.
